(19) United States
(12) Patent Application Publication
(10) Pub. No.: US 2025/0370066 A1
(43) Pub. Date: Dec. 4, 2025

(54) POWER LINE MONITORING APPARATUS AND METHOD OF USE THEREOF

(71) Applicants: Mike Hollingshaus, Livermore, CA (US); James W. Haywood, Boerne, TX (US); Mark Amato, S.Hamilton, MA (US); W. Davis Lee, Rockport, MA (US)

(72) Inventors: Mike Hollingshaus, Livermore, CA (US); James W. Haywood, Boerne, TX (US); Mark Amato, S.Hamilton, MA (US); W. Davis Lee, Rockport, MA (US)

(21) Appl. No.: 18/676,808

(22) Filed: May 29, 2024

(51) Int. Cl. G01R 31/58; G01W 1/00; G01W 1/06; G08C 17/02

(52) U.S. Cl. CPC G01R 31/58; G01W 1/06; G08C 17/02; G01W 2001/006

(57) ABSTRACT

The invention comprises an apparatus and method of use thereof for measuring state of a power line grid using sets of sensor arrays mounted to individual poles and/or wires of a grid of power lines. In one embodiment, an apparatus for measuring state of a power line grid comprises: a main controller and a sensor array communicatively linked to the main controller, the sensor array comprising: a first set of sensors attached to a first powerline between first pole members of the set of poles and a second set of sensors positioned within one hundred feet of second pole members of the set of poles, where the sensors comprise an accelerometer, an anemometer, a temperature sensor, a barometric pressure sensor, a camera, and/or a light sensor.

### BACKGROUND OF THE INVENTION

### Field of the Invention

The invention relates generally to monitoring power lines.

### DISCUSSION OF THE PRIOR ART

### Problem

There exists in the art a need for a monitoring power lines.

### SUMMARY OF THE INVENTION

The invention comprises a power line monitoring apparatus and method of use thereof.

### DESCRIPTION OF THE FIGURES

A more complete understanding of the present invention is derived by referring to the detailed description and claims when considered in connection with the

Figures, wherein like reference numbers refer to similar items throughout the Figures.

FIG. 1 illustrates a control system using a sensor array;

FIG. 2 illustrates a power line monitoring sensor array and controller;

FIG. 3 illustrates power sources;

FIG. 4 illustrates communication systems;

FIG. 5A illustrates multiple sensor arrays;

FIG. 5B illustrates sensor types;

FIG. 5C illustrates sensor clusters;

FIG. 6 illustrates communication linkages; and

FIG. 7 illustrates multiple sensor lines monitoring an area.

Elements and steps in the figures are illustrated for simplicity and clarity and have not necessarily been rendered according to any particular sequence. For example, steps that are performed concurrently or in different order are illustrated in the figures to help improve understanding of embodiments of the present invention.

### DETAILED DESCRIPTION OF THE INVENTION

The invention comprises an apparatus and method of use thereof for measuring state of a power line grid using sets of sensor arrays mounted to individual poles and/or wires of a grid of power lines. Data from the sensors is collected and used to determine state of the power line grid as a function of location. In one embodiment, an apparatus for measuring state of a power line grid comprises: a main controller and a sensor array communicatively linked to the main controller, the sensor array comprising: a first set of sensors attached to a first powerline between first pole members of the set of poles and a second set of sensors positioned within one hundred feet of second pole members of the set of poles, where the sensors comprise an accelerometer, an anemometer, a temperature sensor, a barometric pressure sensor, a camera, and/or a light sensor.

Herein, a z-axis is aligned with gravity and an x/y-plane is perpendicular to the z-axis, such as flat ground.

### Monitoring System

Generally a monitoring system monitors one or more set of sensor arrays to determine the state of a system and/or a state of a system sub-system or component.

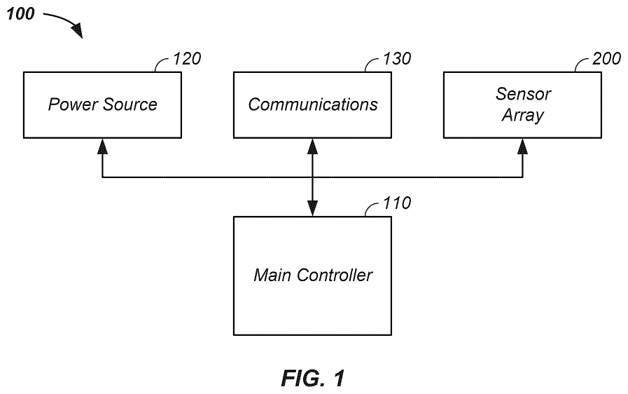

Referring now to FIG. 1, a first example of a monitoring system 100 is illustrated. Generally, a main controller 110 is powered with one or more power sources 120 and communicates using a communication system 130 with one or more sensors in one or more sensor arrays 200. The power sources 120 are optionally used to power the communication 130 and/or the sensor array 200. The communications 130 are optionally linked to the power sources 120 and/or the sensor arrays 200.

For clarity of presentation and without loss of generality, the monitoring system 100 is described using a power line monitoring example. More generally, the monitoring system 100 is used to monitor any two or more arrays of sensors connected to an extended system, such as piers in a wharf, pipelines, or oil rigs.

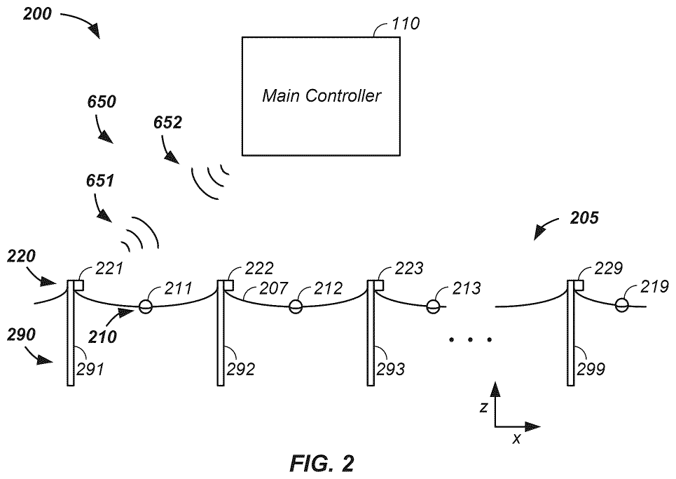

Referring now to FIG. 2, a power line monitoring system 200 is illustrated. In the power line monitoring system 200, the main controller 110 is linked to one or more power lines 205. As illustrated, the power lines 205 includes a set of poles 290, such as a first pole 291, a second pole 292, a third pole 293, . . . , and an n^{th} pole 299, where n is a positive integer, such as greater than 10, 100, 1,000, or 10,000. Optionally and preferably, the sensor array 120 includes a first set of sensors 210 and a second set of sensors 220, described infra.

Still referring to FIG. 2, the first set of sensors 210 are optionally and preferably attached to an individual power line 207. The first set of sensors 210 or power line sensors includes a first power line sensor 211, a second power line sensor 212, a third power line sensor 213, . . . , and an n^{th} power line sensor 219, where n is a positive integer, such as greater than 10, 100, 1,000, or 10,000. Sensors in the first set of sensors 210 are designed to measure condition of the individual power line 207 at known locations, such as measured by GPS or placed at specific known locations during installation, such as between each power line pole, between every other power line pole, and/or at known distances along the power line 205, such as at every 0.1, 0.2, 0.5, 1, 2, 5, or 10 miles or with separation distance exceeding and/or less than 0.1, 0.2, 0.5, 1, 2, 5, or 10 miles. Optionally and preferably, members of the power line sensors are placed at positions along the power line between successive poles, greater than 5, 10, 15, 20, 25, 50, or 100 feet from a power line pole, at local minima of z-axis heights of the power line above local terrain, and/or within 5, 10, 25, 50, or 100 feet of minima of z-axis heights above local minima of z-axis heights of the power line above local terrain.

Still referring to FIG. 2, members the second set of sensors 220 are optionally and preferably attached to corresponding individual power line poles of the set of poles 280. The second set of sensors 220 or power pole positioned sensors includes a first pole positioned sensor 221, a second power pole positioned sensor 222, a third power pole positioned sensor 223, . . . , and an n^{th} power pole positioned sensor 229, where n is a positive integer, such as greater than 10, 100, 1,000, or 10,000. Sensors in the second set of sensors 220 are designed to measure condition of the individual power line 207 at known locations, such as measured by GPS or placed at specific known locations during installation, such as at each power line pole, at every other power line pole, and/or at known distances along the power line 205, such as at every 0.1, 0.2, 0.5, 1, 2, 5, or 10 miles or with separation distance exceeding and/or less than 0.1, 0.2, 0.5, 1, 2, 5, or 10 miles. Optionally and preferably, members of the power pole positioned sensors are placed at positions relative to each pole, such as at the top of the pole, at the bottom of the pole, within 5, 10, 15, 25, 50, 100, or 200 feet of the pole, and/or within 1, 2, 5, 10, 15, 25, or 50 feet of the top of the pole or the bottom of the pole.

Still referring to FIG. 2, at least some elements of the first set of sensors 210, the power line sensors, measure movement of the power line, such as due to wind, weather, rain, snow, and/or ice. For instance, one or more sensors of the first set of sensors 210 include a first cluster of sensors, further described infra. A first cluster of sensors includes one or more sensors. In this case, the one or more sensors and/or the first cluster of sensors of the first set of sensors 210 includes one of more of: an accelerometer to measure localized movement of the power line at the known location, a temperature monitor, a power supply, such as from the power sources 120, and/or a parasitic power source inductively coupled to the power line, such as the individual power line 207. The first set of sensors 210 are optionally and preferably used to measure weather induced movement of the power line at the known location of individual members of the first set of sensors 210, such as induced by wind. For instance, an accelerometer measures wind induced motion or dampened motion relative to sensed wind, such as when ice forms on the power lines.

Still referring to FIG. 2, at least some elements of the second set of sensors 220, the power pole positioned sensors, measure local conditions, such as weather, localized power through the line, state of the pole, and/or state of the line. For instance, one or more sensors of the second set of sensors 210 include a second cluster of sensors, further described infra. A second cluster of sensors includes one or more sensors. In this case, the one or more sensors and/or the second cluster of sensors of the second set of sensors 210 includes one of more of: a camera to monitor the power line and/or the power pole, an accelerometer to measure localized movement of the power pole at the known location, a temperature monitor, a weather station containing one or more weather monitoring sensors, a power supply, such as from the power sources 120, and/or a parasitic power source inductively coupled to the power line, such as the individual power line 207. The second set of sensors 210 are optionally and preferably used to measure weather induced changes to the power line, such as the individual power line 207, at or about the known position of the local power pole. In one example, a fallen pole would have an accelerometer reading and a location indicating that the pole fell for use by repair crews.

Still referring to FIG. 2, any element of the first set of sensors 210 is optionally present in any of the second set of sensors 220 and vise-versa.

Still referring to FIG. 2, a transmitter and/or a receiver is optionally and preferably present with each installation of the first set of sensors 210 and/or the second set of sensors 220. Thus, the sensors optionally and preferably communicate, such as sending data collected from the sensors and/or information derived therefrom to the main controlled through the communications 130. As illustrated, the signals are sent along the line and/or optionally and preferably wirelessly, such as in a wireless communication system 650 with signals sent from the power line 651 directly and/or indirectly to the main controller 110 and/or transmitted 652 from the main controller 110 to the power line. Signals are optionally sent parallel to the line and/or between power lines as further described infra. Optionally, one or more sub-communication systems 203 gather information from various sensors along the power line before transmitting to a local tower and/or to the main controller, as further described infra.

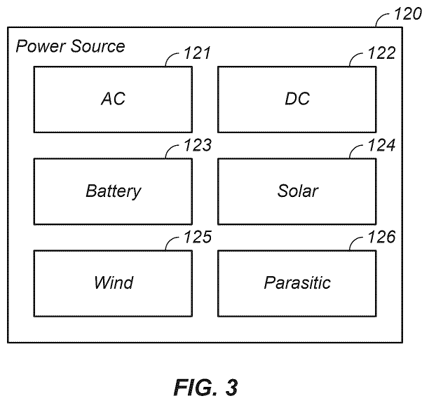

Referring now to FIG. 3, the power source 120 is further described. Optionally, the power source, linked to one or more of the individual sensors, cluster of sensors, the communications 130, and/or the sensor arrays 200, includes one or more of: AC power 121, DC power 122, a converter, and inverter, a battery 123, solar power 124, wind derived power 125, and/or parasitic power 126, such as pulled from the power line.

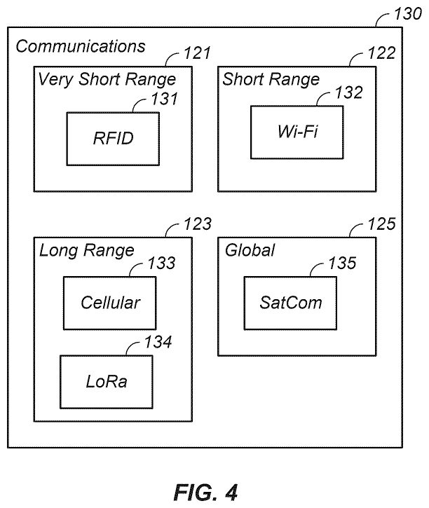

Referring now to FIG. 4, the communications 130 also referred to as a communications system is further described. The communications 130 are optionally linked to any one or more element of the monitoring system 100, such as to individual sensors of the sensor arrays 200, the sensor arrays 200, any one or more poles of the power line, any intermediate tower, and/or any intermediate communication network connected directly and/or indirectly to the main controller 110. The communications 130 optionally and preferably include one or more of: very short range communications 121, such as radio-frequency identification (RFID) communications 131; short range communications 122, such as Wi-Fi 132 or Bluetooth; long range communications 123, such as cellular 123 or long range radio (LoRa) 134; and/or global communications 124, such as satellite communications (SatCom) 135.

### Sensor Array

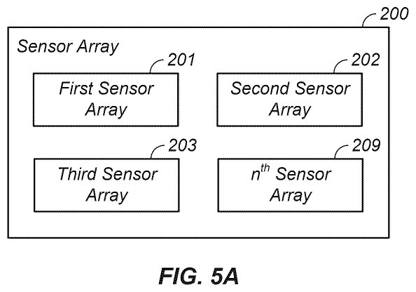

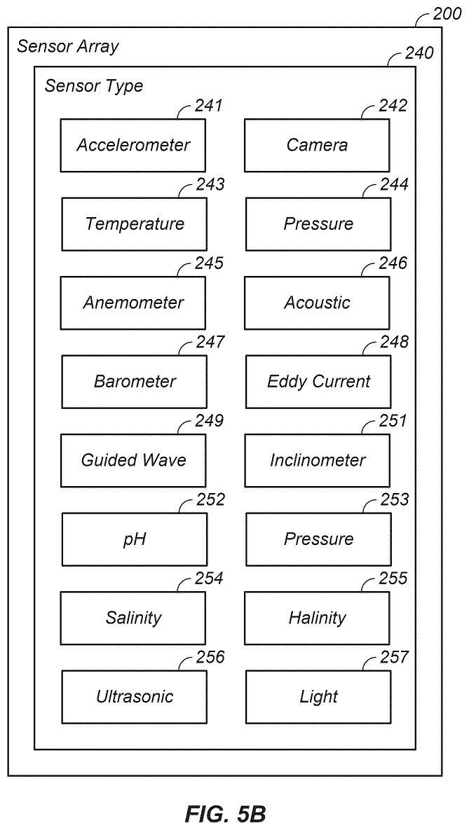

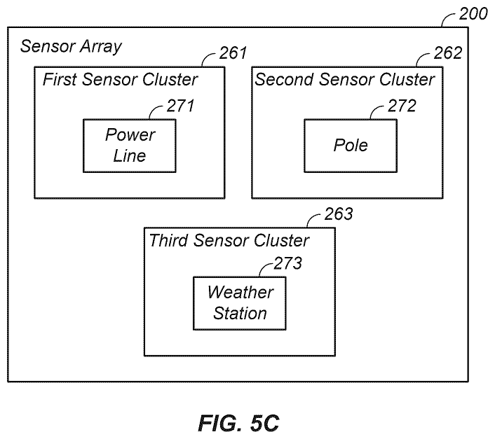

Referring now to FIG. 5A, FIG. 5B, and FIG. 5C, the sensor array 200 is further described.

Referring now to FIG. 5A, the sensor array 200 preferably includes 2, 3, 4, or more individual sensor arrays or clusters of sensors, such as the first set of sensors 210 (wire positioned sensors) and the second set of sensors 220 (pole positioned sensors), described supra. For instance, the sensor array 200 optionally includes one or more of a first sensor array 201, a second sensor array 202, a third sensor array 203, . . . , and an nth sensor array 209, where n is a positive integer greater than 1, 2, 3, 4, 5, 10, 15.

Referring now to FIG. 5B, the sensor array 200 optionally and preferably includes one or more sensor types 240, such as one or more of: an accelerometer 241, a camera 242, a temperature sensor 243, a pressure sensor 244, an anemometer 245, an acoustic sensor 246, a barometer 247, and eddy current sensor 248, a guided wave sensor 249, an inclinometer 251, a pH sensor 252, a pressure sensor 253, a salinity sensor 254, a salinity sensor 255, an ultrasonic sensor 256, and/or a light sensor 257.

Referring now to FIG. 50, the sensor array 200 optionally and preferably includes an array of sensor clusters. Any 2, 3, 4, or more sensors positioned together in a container is referred to as a sensor cluster herein. For instance, when two or more sensors are co-positioned as a member of the first set of sensors 210 or power line sensors, the co-positioned sensors are an example of a first sensor cluster 261 mounted to a specific power line 262. Similarly, when two or more sensors are co-positioned as a member of the second set of sensors 220 or power pole positioned sensors, the co-positioned sensors are an example of a second sensor cluster 262 mounted to an individual pole 272. An example of a third sensor cluster 263 is a weather station 273, which includes any two or more of the sensor types 240 when used to measure weather and/or the impact of weather on the power lines.

### Communications

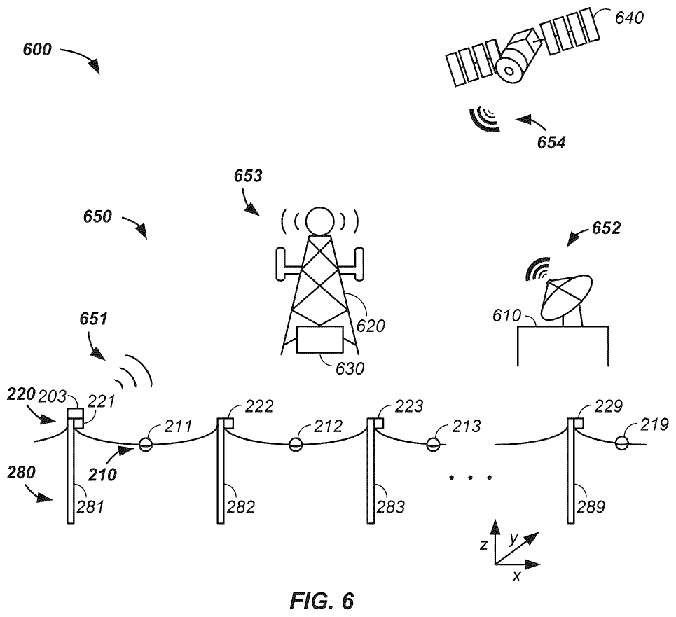

Referring now to FIG. 6, the communications 130 are further described. Here, the wireless communication system 650 is further described. The wireless communication system 650 optionally includes a base station 610, such as housing a version of the main controller 110 or the main controller 110, the main controller 110 is optionally located anywhere, such as in/on a tower 620, such as housing a data collector/transceiver 630 communicatively linked with the main controller 110 and the sub-communication systems 203 sending receiving first optional communications 652. A satellite 640 is optionally used to relay second optional communications 653 as part of a communication line from sensors of the monitoring system to the main controller 110.

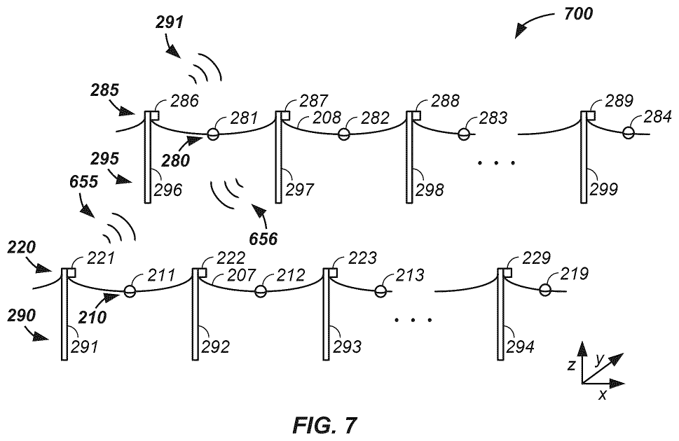

Referring now to FIG. 7, monitoring areas, as opposed to lines, and communications between lines is described. As illustrated, the first and second sensor arrays 210, 220 on the individual power line are optionally repeated on any number of power lines, which brings a benefit of adding information about a power line grid or area covered by the power lines. For example, a third set of sensors 280 and a fourth set of sensors 285 are illustrated on a second power line. The third set of sensors 280 includes any of the sensors of the first set of sensors 210, such as in a first cluster 282, a second cluster 282, a third cluster 283, . . . , and an n^{th} cluster 284 on a second power line 208, where n is a positive integer greater than 2, 5, 10, 100, 1000, or 10,000. Each cluster has any number of sensors, such as from the sensor types 240. Similarly, the fourth set of sensors 285 includes any of the sensors of the second set of sensors 210, such as in a sixth cluster 286, a seventh cluster 287, an eighth cluster 28, and/or an ninth cluster 289 on the second power line 208, where each set of sensors optionally has any number/type of sensors, such as from the sensor types 240, at n locations where n is a positive integer greater than 2, 5, 10, 100, 1000, or 10,000. As illustrated, the communications 130 optionally and preferably contain communications between any element of the individual power line 207 and the second power line 208, such as via fifth and sixth transmitter and/or receivers 655, 656. By extension, the communications 130 optionally extended between any number of power lines to cover a power line grid or area.

Optionally, data, such as weather data, along with location of source of the data is provided, optionally for a fee, to a weather service.

Referring again to FIG. 1, the main controller 110 is further described. The main controller 110, having received localized state of the weather and/or state of the power line grid from the sensor arrays 200 is optionally and preferably used to provide summary information for decision making about the state of the power grid at any monitored location and/or between monitored locations by differential signals. Several non-limiting examples follow.

### Example I

A monitoring device is mounted to a power line or conductor that monitors the motion of that conductor. If and when that motion is large enough either in amplitude or frequency to cause concern based on a pre-determined metric, an action will be taken. For instance, the action is optionally to divert power from a section of the grid, in advance of a fault, depending on the severity of the data and thus provides capability to react proactively before an unintended fault or catastrophic failure.

### Example II

A monitor device package includes a motion sensor affixed to the power conductor. As the power cable moves the device measures and optionally records this motion. Recording is optionally continuous and/or is triggered, such as via motion amplitude, motion frequency, a fixed offset to an initial parameter, such as an initial static angle change related to some secondary final angle.

### Example III

The monitor device package optionally includes a global positioning sensor.

### Example IV

The monitor device package optionally and preferably includes a power source. This power source may be one or more of the following: battery, solar powered, wind powered, parasitically powered (i.e. couples energy from the power conductor it is mounted to). Power sources optionally work together, such as a solar array and a battery for low/no sun times, a parasitic power source, and a battery to be used should the power be shut off intentionally or by accident or damage.

### Example V

This monitor device package will possibly communicate with a fixed or relatively fixed object, such as a station on a support tower. This fixed object may be close by (possibly WiFi range˜100 m) or may be fairly far away (LoRa range>10 km). The monitor device may be able to communicate at multiple distances via one or more communication method.

### Example VI

The monitor device package optionally communicates with additional devices having different metrology. For example, a monitor device package on a power conductor might communicate with a weather station mounted on an adjacent or nearby tower. The weather station might include any or all of the following: a temperature sensor(s), an anemometer, a wind direction indicator, a barometer, a hygrometer, a precipitation measurement device. Any, all or a combination of these measurements might be used as a trigger for the monitor device package to record or transmit data. As an example, if the wind speed were measured at over 10, 20, 30, 40, 50, 60, 80, or 100 mph the monitor device package is optionally triggered to record data and send it to a data collection and storage device.

### Example VII

The monitor device package optionally receives data from an external source, either directly or indirectly through a fixed mounted device or another monitor device package. For example, the monitor device package might receive information from a local meteorological station, or a seismic station, or based on some information available on the world wide web. These received data may be used to trigger the monitor device package to record and or transmit data, or to do something else like reboot, start a measurement, activate a different piece of metrology, turn on a camera, reposition a camera, etc.

### Example VIII

The monitor device package is optionally placed in the middle of a span of power conductor so as to receive the largest displacement during motion. The device monitor package might be placed at a location closer to one end than the other in an effort to capture different spatial frequencies of the power conductor motion. A particular span of power conductor may carry more than one monitor device package, in an effort to better resolve the spatial frequencies of the power conductor motion.

### Example IX

The spatial distribution of the sensors in the sensor array 200 is optionally a function of local population density, historical wind speeds, population density, and/or proximity of high value systems.

### Example X

A signal from the first set of sensors on the power line is optionally used to control timing of collection of data from the second set of sensors mounted to the poles or vise-versa.

### Example XI

A first set of sensors is positioned on movable/swayable power lines and a second set of sensors is mounted to a relatively static mount, such as a support pole, a ground line, and/or to the ground. Both sets of sensors send power grid state data to the main controller 110.

Still yet another embodiment includes any combination and/or permutation of any of the elements described herein.

Herein, any number, such as 1, 2, 3, 4, 5, is optionally more than the number, less than the number, or within 1, 2, 5, 10, 20, or 50 percent of the number.

The particular implementations shown and described are illustrative of the invention and its best mode and are not intended to otherwise limit the scope of the present invention in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in a practical system.

In the foregoing description, the invention has been described with reference to specific exemplary embodiments; however, it will be appreciated that various modifications and changes may be made without departing from the scope of the present invention as set forth herein. The description and figures are to be regarded in an illustrative manner, rather than a restrictive one and all such modifications are intended to be included within the scope of the present invention. Accordingly, the scope of the invention should be determined by the generic embodiments described herein and their legal equivalents rather than by merely the specific examples described above. For example, the steps recited in any method or process embodiment may be executed in any order and are not limited to the explicit order presented in the specific examples. Additionally, the components and/or elements recited in any apparatus embodiment may be assembled or otherwise operationally configured in a variety of permutations to produce substantially the same result as the present invention and are accordingly not limited to the specific configuration recited in the specific examples.

Benefits, other advantages and solutions to problems have been described above with regard to particular embodiments; however, any benefit, advantage, solution to problems or any element that may cause any particular benefit, advantage or solution to occur or to become more pronounced are not to be construed as critical, required or essential features or components.

As used herein, the terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present invention, in addition to those not specifically recited, may be varied or otherwise particularly adapted to specific environments, manufacturing specifications, design parameters or other operating requirements without departing from the general principles of the same.

Although the invention has been described herein with reference to certain preferred embodiments, one skilled in the art will readily appreciate that other applications may be substituted for those set forth herein without departing from the spirit and scope of the present invention. Accordingly, the invention should only be limited by the Claims included below.

1. An apparatus for measuring state of a power line grid, the power line grid comprising a set of poles, a first powerline, and a second powerline, said apparatus comprising:
a main controller; and
a sensor array communicatively linked to said main controller, said sensor array comprising:
a first set of sensors attached to the first powerline between first pole members of the set of poles; and
a second set of sensors positioned within one hundred feet of second pole members of the set of poles.

2. The apparatus of claim 1, said second set of sensors attached to the second pole members of the set of poles.

3. The apparatus of claim 1, said first set of sensors comprising a first sensor cluster comprising:
an accelerometer.

4. The apparatus of claim 3, said accelerometer mounted within ten feet of a local minimum height of the first powerline between a first pole and a second pole of the set of poles.

5. The apparatus of claim 3, said second set of sensors comprising a second sensor cluster comprising:
an anemometer.

6. The apparatus of claim 5, at least one of said first sensor cluster and said second sensor cluster further comprising:
a temperature sensor; and
a barometric pressure sensor.

7. The apparatus of claim 6, at least one of said first sensor cluster and said second sensor cluster further comprising at least one of:
a camera; and
a light sensor.

8. The apparatus of claim 7, said camera configured to sense movement of at least one pole of the set of poles.

9. The apparatus of claim 6, said sensor array further comprising:
a parasitic power supply configured to draw power from the first powerline.

10. The apparatus of claim 9, further comprising:
a first sub-communication system positioned within one thousand feet of the first powerline, said first sub-communication system configured to relay data from said sensor array to said main controller.

11. The apparatus of claim 10, further comprising:
a second sub-communication system communicatively linked to said first sub-communication system, said first sub-communication system configured to relay data from first sensors, of said sensor array, positioned within ten feet of the first power line to said main controller, said second sub-communication system configured to relay data from second sensors, of said sensor array, positioned within ten feet of the second power line to said first sub-communication system, the second power line no closer than one hundred feet from the first power line.

12. The apparatus of claim 6, further comprising:
known locations of elements of said sensor array, said known locations spanning a distance of greater than ten miles.

13. The apparatus of claim 1, said sensor array configured to measure weather induced movement of the power line at two distances separated by greater than ten miles.

14. The apparatus of claim 1, said main controller configured to gather weather related data from said sensor array.

15. The apparatus of claim 1, said sensor array positioned along lengths of the first power line and the second powerline, the first powerline and the second powerline forming an angle therebetween of greater than forty five degrees and less than one hundred thirty five degrees at an intersection zone between the first powerline and the second powerline.

16. The apparatus of claim 1, said sensor array positioned along lengths of at least ten separate powerlines of the power line grid.

17. An apparatus for measuring state of a power line grid, the power line grid comprising a set of poles and a powerline, said apparatus comprising:
a main controller; and
a sensor array communicatively linked to said main controller, said sensor array comprising:
a first set of sensors positioned along a length of the powerline, wherein multiple members of said first set of sensors each comprise a set of sensor clusters; and
a first set of sensor types, comprising at least three of:
an accelerometer;
a camera;
a temperature sensor;
a barometric pressure sensor;
an anemometer; and
a light sensor,
wherein multiple elements of said set of sensor clusters each comprise said first set of sensor types.

18. The apparatus of claim 17, said sensor array further comprising:
a first cluster of sensors attached to the powerline between a first two poles of the set of poles;
a second cluster of sensors attached to the powerline between a second two poles of the set of poles; and
a third cluster of sensors attached to the powerline between a third set of poles.
